(19) United States
(12) Patent Application Publication
(10) Pub. No.: US 2025/0372584 A1
(43) Pub. Date: Dec. 4, 2025

(54) ELECTRONIC DEVICE

(71) Applicant: Advanced Semiconductor Engineering, Inc., Kaohsiung (TW)

(72) Inventors: Ming-Hao HSIEH, Kaohsiung (TW); Chien-Wei CHANG, Kaohsiung (TW); Wen Hung HUANG, Kaohsiung (TW); Min Lung HUANG, Kaohsiung (TW)

(73) Assignee: Advanced Semiconductor Engineering, Inc., Kaohsiung (TW)

(21) Appl. No.: 18/731,221

(22) Filed: May 31, 2024

(51) Int. Cl. H01L 25/10; H01L 23/00; H01L 23/31; H01L 23/498

(52) U.S. Cl. CPC H01L 25/105; H01L 23/3135; H01L 23/49827; H01L 24/16; H01L 2224/16235; H01L 2225/1041; H01L 2225/1058; H01L 2924/182

(57) ABSTRACT

An electronic device is provided. The electronic device includes an electronic component, a first encapsulant, a second encapsulant, and a first power regulating component. The encapsulant has an active surface and a backside surface configured to receive a first power. The first encapsulant at least partially encapsulates the electronic component. The second encapsulant is disposed under the first encapsulant. The first power regulating component is configured to transmit the first power to the electronic component and at least partially embedded within the second encapsulant.

### BACKGROUND

### 1. Field of the Disclosure

The present disclosure relates to an electronic device, and particularly to an electronic device integrating an electronic component configured to receive power by a backside surface.

### 2. Description of the Related Art

In an electronic device, the integration of a power regulating component with an electronic component can be impacted by the distance of the power transmission path, affecting the performance of the electronic device. To improve the performance of the electronic device, a new electronic device is necessary.

### SUMMARY

In some embodiments, an electronic device includes an electronic component, a first encapsulant, a second encapsulant, and a first power regulating component. The encapsulant has an active surface and a backside surface configured to receive a first power. The first encapsulant at least partially encapsulates the electronic component. The second encapsulant is disposed under the first encapsulant. The first power regulating component is configured to transmit the first power to the electronic component and at least partially embedded within the second encapsulant.

In some embodiments, an electronic device includes an electronic component, a power regulating component, and a first interconnection structure. The electronic component has an active surface and a backside surface configured to receive a power. The power regulating component is configured to transmit the power to the electronic component. The first interconnection structure is disposed at a side of the power regulating component configured to transmit the power.

In some embodiments, an electronic device includes a first interposer, a power regulating component, and an electronic component. The power regulating component is embedded within the first interposer and includes a terminal exposed by the first interposer. The electronic component is bonded to the terminal of the power regulating component. The electronic component has an active surface and a backside surface configured to receive a power from the power regulating component.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 illustrates a cross-sectional view of an example of an electronic device according to some embodiments of the present disclosure.

FIG. 2 is a partial enlarged view of the electronic device shown in FIG. 1A according to some embodiments of the present disclosure.

FIG. 3 is a partial enlarged view of the electronic device shown in FIG. 1A according to some embodiments of the present disclosure.

FIG. 4A, FIG. 4B, FIG. 4C, FIG. 4D, FIG. 4E, FIG. 4F, FIG. 4G, FIG. 4H, FIG. 4I, FIG. 4J, FIG. 4K, FIG. 4L, FIG. 4M, FIG. 4N, FIG. 4O, FIG. 4P, FIG. 4Q, FIG. 4R, FIG. 4S, FIG. 4T, and FIG. 4U illustrate various stages of an example of a method for manufacturing an electronic device according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides for many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

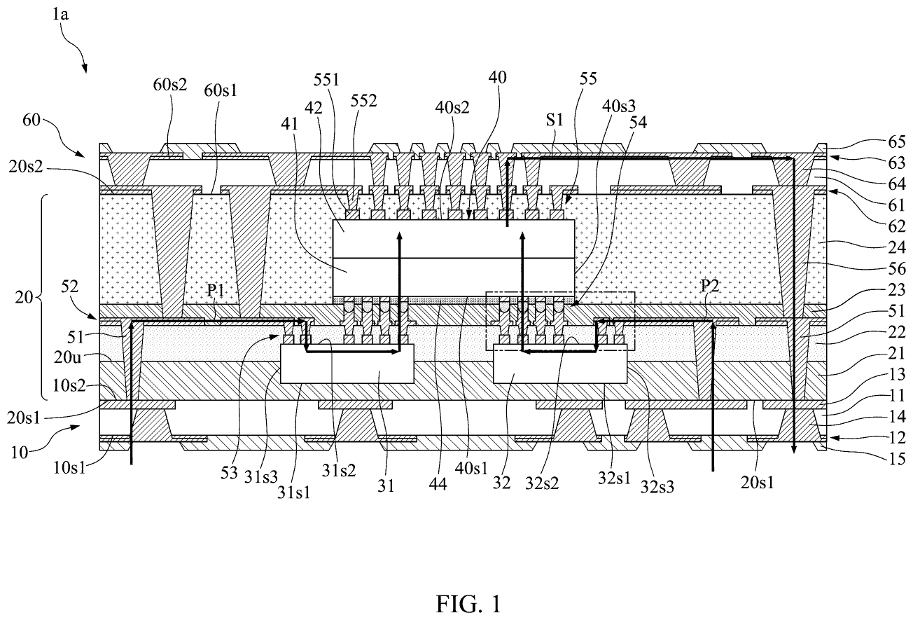

FIG. 1A illustrates a cross-sectional view of an electronic device 1a according to some embodiments of the present disclosure. In some embodiments, the electronic device 1a may include a circuit structure 10, a carrier 20, a power regulating component 31, a power regulating component 32, an electronic component 40, interconnection structures 51, a redistribution layer 52, interconnection structures 56, and a circuit structure 60.

The circuit structure 10 may include a substrate 11, a conductive layer 12, a conductive layer 13, an interconnection 14, and a dielectric layer 15. The circuit structure 10 may have a surface 10s1 (or a lower surface) and a surface 10s2 (or an upper surface) opposite to the surface 10s1.

The substrate 11 may be a core substrate. The core substrate may include prepreg (PP), Ajinomoto build-up film (ABF) or other suitable materials. In some embodiments, a resin material used in the core substrate may be a fiber-reinforced resin so as to strengthen the core substrate, and the reinforcing fibers may be, without limitation to, glass fibers or Kevlar fibers (aramid fibers). The lower surface of the substrate 11 may be defined as the surface 10s1. The upper surface of the substrate 11 may be defined as the surface 10s2.

The conductive layer 12 may be disposed under, within, and/or adjacent to the surface 10s1 of the circuit structure 10. The conductive layer 12 may be electrically connected to an external device (not shown), such as a printed circuit board (PCB) or other suitable components. The conductive layer 13 may be disposed over, within, and/or adjacent to the surface 10s2 of the circuit structure 10. The interconnection 14 may be disposed within the substrate 11. The interconnection 14 may electrically connect the conductive layer 12 to the conductive layer 13. The interconnection 14 may include a conductive via, which is tapered toward the surface 10s2 of the circuit structure 10. Each of the conductive layer 12, conductive layer 13, and interconnection 14 may include a seed layer and a conductive material on the seed layer. The seed layer may include metal, metal oxide, metal nitride, metal carbide, metal alloy, or suitable materials. For example, the seed layer may include tantalum nitride, tantalum, titanium nitride, titanium, cobalt tungsten, tungsten nitride, or the like. The conductive material may include copper, aluminum, tungsten, chromium, gold, silver, other suitable materials, or a combination thereof.

The dielectric layer 15 may be disposed under the surface 10s1 of the circuit structure 10. The dielectric layer 15 may be patterned to expose a portion of the conductive layer 12. The dielectric layer 15 may include a solder resist, such as a polymer material including bismaleimide triazine, polypropylene or an epoxy-based material.

In some embodiments, the carrier 20 may be disposed on or over the surface 10s2 of the circuit structure 10. The carrier 20 may be configured to encapsulate the power regulating components 31 and 32, the electronic component 40, the interconnection structures 51, the redistribution layer 52, and the interconnection structures 56. The carrier 20 may be configured to transmit power (e.g., non-regulated power and/or regulated power) and/or a signal. The carrier 20 may have a surface 20s1 (or a lower surface) abutting the circuit structure 10 and a surface 20s2 (or an upper surface) opposite to the surface 20s1. In some embodiments, the carrier 20 may include encapsulants 21, 22, 23, and 24.

In some embodiments, the encapsulant 21 may be disposed on the surface 10s2 of the circuit structure 10. In some embodiments, the encapsulant 21 may be in contact with the substrate 11. The encapsulant 21 may include an insulation or dielectric material. In some embodiment, the encapsulant 21 may be made of molding material that may include, for example, a novolac-based resin, an epoxy-based resin, a silicone-based resin, or other suitable materials. In some embodiments, the encapsulant 21 may include, for example, organic materials (e.g., a molding compound, a bismaleimide triazine, polyimide, polybenzoxazole, a polypropylene, or an epoxy-based material), inorganic materials (e.g., a silicon, a glass, a ceramic or a quartz), liquid and/or dry-film materials or a combination thereof.

In some embodiments, the encapsulant 22 may be disposed on or over the encapsulant 21. The encapsulant 22 may be in contact with the encapsulant 21. In some embodiments, the material of the encapsulant 22 may be the same as or similar to that of the encapsulant 21. In some embodiments, the thickness of the encapsulant 22 may be substantially the same as that of the encapsulant 21. In other embodiments, the thickness of the encapsulant 22 may be different from that of the encapsulant 21.

In some embodiments, the encapsulant 23 may be disposed on or over the encapsulant 22. The encapsulant 23 may be in contact with the encapsulant 22. In some embodiments, the encapsulant 23 may be configured to encapsulate the redistribution layer 52. In some embodiments, the material of the encapsulant 23 may be the same as or similar to that of the encapsulant 21. In some embodiments, the thickness of the encapsulant 23 may be less than that of the encapsulant 21.

In some embodiments, the encapsulant 24 may be disposed on or over the encapsulant 23. The encapsulant 24 may be in contact with the encapsulant 23. In some embodiments, the encapsulant 24 may be configured to encapsulate the electronic component 40. In some embodiments, the material of the encapsulant 24 may be the same as or similar to that of the encapsulant 21. In some embodiments, the thickness of the encapsulant 24 may be greater than that of the encapsulant 21. In some embodiments, the thickness of the encapsulant 24 may be greater than that of the encapsulant 23.

In some embodiments, each of the encapsulants 21, 22, 23, 24, a combination thereof, and other features therein may function as a part of an interposer. For example, the encapsulant 21, the encapsulant 22, and the interconnection structures 51 may function as a first interposer; the encapsulant 23, the encapsulant 24, and the interconnection structures 56 may function as a second interposer.

In some embodiments, a portion of the power regulating component 31 may be embedded within the encapsulant 21. In some embodiments, a portion of the power regulating component 31 may be embedded within the encapsulant 22. The power regulating component 31 may be configured to regulate power. In some embodiments, the power regulating component 31 may include a power management IC (PMIC) or other suitable elements. The power regulating component 31 may have a surface 31s1 (or a lower surface), a surface 31s2 (or an upper surface), and a surface 31s3 (or a lateral surface or a side) extending between the surface 31s1 and surface 31s2. The surface 31s2 may function as an active surface that is configured to transmit a regulated power and/or a signal. In some embodiments, the surface 31s1 may be spaced apart from the circuit structure 10 by the encapsulant 21. An interface 20u between the encapsulants 21 and 22 may intersect or be in contact with the surface 31s3 of the power regulating component 31.

In some embodiments, a portion of the power regulating component 32 may be embedded within the encapsulant 21. In some embodiments, a portion of the power regulating component 32 may be embedded within the encapsulant 22. The power regulating component 32 may be configured to regulate power. In some embodiments, the power regulating component 32 may include PMIC or other suitable elements. In some embodiments, the power regulating component 31 and the power regulating component 32 may be arranged side by side. The power regulating component 32 may have a surface 32s1 (or a lower surface), a surface 32s2 (or an upper surface), and a surface 32s3 (or a lateral surface or a side) extending between the surface 32s1 and surface 32s2. The surface 32s2 may function as an active surface that is configured to transmit a regulated power and/or a signal. In some embodiments, a non-regulated power may be referred to as the first power, and a regulated power may be referred to as the second power.

In some embodiments, each of the power regulating component 31 and power regulating component 32 may include terminals 53. The terminals 53 may be embedded within the encapsulant 22. The terminals 53 may be electrically connected to the redistribution layer 52. Each of the terminals 53 may be exposed by the upper surface of the encapsulant 22. The terminal 53 may be disposed on or over surface 31s2 of the power regulating component 31. The terminal 53 may be disposed on or over surface 32s2 of the power regulating component 32. In some embodiments, the terminal 53 may include multiple stacked conductive elements.

In some embodiments, the electronic component 40 may be disposed on or over the power regulating component 31 and power regulating component 32. In some embodiments, the power regulating component 31 may be closer to the circuit structure 40 than the electronic component 40 is. In some embodiments, the electronic component 40 may be disposed on or over the encapsulant 23. In some embodiments, the electronic component 40 may overhang the power regulating component 31. In some embodiments, the electronic component 40 may overhang the power regulating component 32. The electronic component 40 may be free from laterally overlapping the power regulating component 31 and power regulating component 32. In some embodiments, the electronic component 40 may be embedded within the encapsulant 24. In some embodiments, an adhesive layer 44 may be disposed between the encapsulant 23 and the electronic component 40. The adhesive layer 44 may include a non-conductive film (NCF) or other suitable materials. The electronic component 40 may have a surface 40s1 (or a lower surface), a surface 40s2 (or an upper surface), and a surface 40s3 (or a lateral surface or a side) extending between the surface 40s1 and surface 40s2. In some embodiments, the thickness of the electronic component 40 may be greater than that of the power regulating component 31. In some embodiments, the surface 40s2 may be covered by the encapsulant 24.

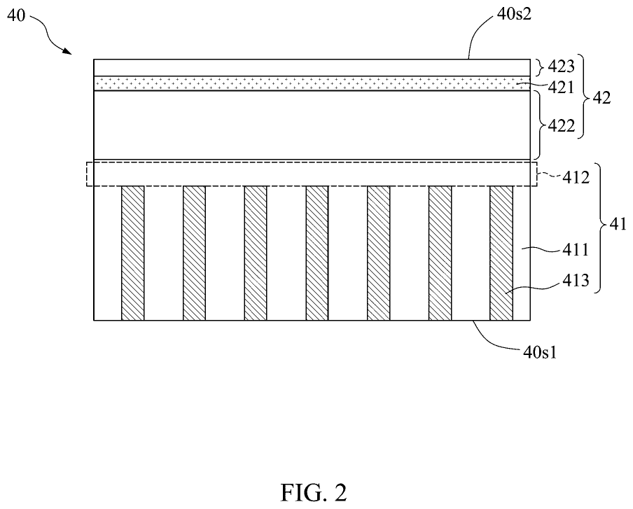

Please refer to FIG. 2, which illustrates an enlarged view of the electronic component 40. In some embodiments, the electronic component 40 may include a passive component 41 and an active component 42 over the passive component 41. In some embodiments, the passive component 41 (or carrier) may be configured to consume, store, and transmit energy. In some embodiments, the passive component 41 may be configured to stabilize, adjust, receive, and/or transmit power. In some embodiments, the passive component 41 may include a capacitor, inductor, resistor, filter, or a combination of such components. The capacitor may include a deep trench capacitor (DTC), a multi-layer ceramic capacitor (MLCC) or other capacitors. The passive component 41 may include a substrate 411, a passive element region 412, and conductive structures 413.

The substrate 411 may include a semiconductor substrate. The substrate 411 may include silicon or germanium in a single crystal form, a polycrystalline form, or an amorphous form. The lower surface of the substrate 411 may function as the surface 40s1 of the electronic component 40, which may also be defines as the backside surface of the electronic component 40.

The passive element region 412 may be embedded in the substrate 411. The passive element region 412 may abut the active component 42. In some embodiments, the passive element region 412 may define one or more capacitors and include a metal-insulator-metal (MIM) structure or other suitable structures.

The conductive structure 413 may extend between the surface 40s1 and the passive element region 412. The conductive structure 413 may penetrate a portion of the substrate 411. The conductive structure 413 may be electrically connected to the passive element region 412. In some embodiments, the conductive structure 413 may include a through silicon via (TSV). The conductive structure 413 may be configured to receive and/or transmit power. The conductive structure 413 may include copper, aluminum, gold, silver, tungsten, nickel, a combination thereof or other suitable materials.

In some embodiments, the active component 42 may be disposed on or over the passive component 41. The active component 42 may be configured to receive power. The active component 42 may be configured to generate and/or process a signal. The active component 42 may include a semiconductor die or a chip, such as a logic die (e.g., application processor (AP), system-on-a-chip (SoC), central processing unit (CPU), graphics processing unit (GPU), microcontroller, etc.), a memory die (e.g., dynamic random access memory (DRAM) die, static random access memory (SRAM) die, etc.), a radio frequency (RF) die, a sensor die, a micro-electro-mechanical-system (MEMS) die, a signal processing die (e.g., digital signal processing (DSP) die), a front-end die (e.g., analog front-end (AFE) dies) or other active components. The upper surface of the active component 42 may function as the surface 40s2 of the electronic component 40, which may also be defined as an active surface. As used herein, the term “active surface” may refer to a surface through which a signal (e.g., I/O signal) passes. In some embodiments, the active component 42 may have an integrated circuit (IC) layer 421, a redistribution structure 422, and a redistribution structure 423.

The IC layer 421 may include one or more ICs formed within the base, such as a semiconductor substrate. The IC layer 421 may be configured to receive power (or a power signal), and generate a signal (or a non-power signal), such as an input/out (I/O) signal or other signals.

The redistribution structure 422 (or a power delivery network (PDN)) may be disposed under the IC layer 421. In some embodiments, the redistribution structure 422 may be configured to receive and/or transmit power, which may include or be composed of direct current (DC), to the IC layer 421. The redistribution structure 422 may include one or more conductive traces and conductive vias embedded within one or more dielectric layers.

The redistribution structure 423 may be disposed over the IC layer 421. The redistribution structure 423 may be configured to receive and/or transmit a signal (e.g., I/O signal), which may include or be composed of alternating current (AC). In some embodiments, the redistribution structure 423 may include one or more conductive traces and conductive vias embedded within one or more dielectric layers.

Please refer back to FIG. 1, the electronic component 40 may include terminals 54 and terminals 55. Each of the terminals 54 may be disposed on or under the surface 40s1 of the electronic component 40. In some embodiments, the terminal 54 may include multiple stacked conductive elements. In some embodiments, the electronic component 40 may be bonded to the power regulating component 31 (or power regulating component 32) through the terminals 54, the redistribution layer 52, and the terminals 53.

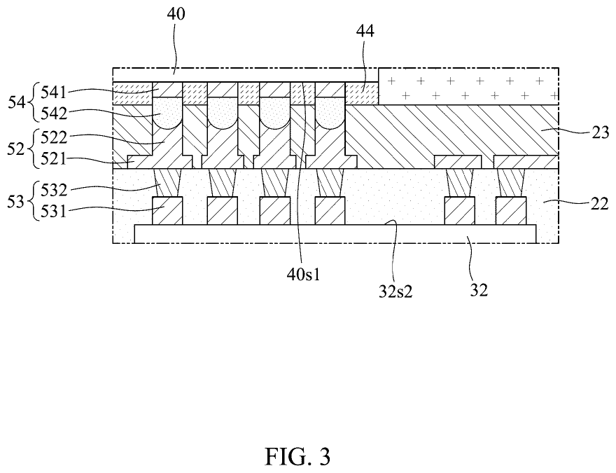

Please refer to FIG. 3, which illustrates a partial enlarged view of the electronic device 1a. In some embodiments, each of the terminals 53 may include a pad 531 and a via 532. The pad 531 may be disposed on or over the surface 32s2 of the power regulating component 32 (or surface 31s2 of the power regulating component 31). The pad 531 may be embedded within the encapsulant 22. The pad 531 may include copper, aluminum, gold, silver, tungsten, nickel, a combination thereof or other suitable materials. The via 532 may be disposed on or over the pad 531. The via 532 may be embedded within the encapsulant 22. The via 532 may be tapered toward the pad 531. In some embodiments, the via 532 may include a seed layer and a conductive material on the seed layer.

The redistribution layer 52 may be disposed on or over the terminal 53. In some embodiments, the redistribution layer 52 may include a conductive layer 521 and a via 522 over the conductive layer 521. Each of the conductive layer 521 and via 522 may include copper, aluminum, gold, silver, tungsten, nickel, a combination thereof or other suitable materials. In some embodiments, the conductive layer 521 may be disposed on or over the encapsulant 22. In some embodiments, the conductive layer 521 may be embedded within the encapsulant 23. The conductive layer 521 may be connected to the via 532. In some embodiments, the upper surface of the conductive layer 521 may be covered by the encapsulant 23. In some embodiments, the via 522 (or conductive pillar) may be disposed on or over the conductive layer 521. In some embodiments, the via 522 may be embedded within the encapsulant 23. In some embodiments, the upper surface of the via 522 may be concaved and recessed downwardly. In some embodiments, the upper surface of the via 522 may be concaved and recessed from the upper surface of the encapsulant 23.

In some embodiments, each of the terminals 54 may include a pad 541 and a conductive element 542. The pad 541 may be disposed on or under the surface 40s1 of the electronic component 40. The pad 541 may be embedded within the adhesive layer 44. The pad 541 may include copper, aluminum, gold, silver, tungsten, nickel, a combination thereof or other suitable materials. The conductive element 542 may be disposed on or under the pad 541. In some embodiments, the conductive element 542 may be partially embedded within the adhesive layer 44. In some embodiments, the conductive element 542 may be partially embedded within the encapsulant 23. The conductive element 542 may be connected to the via 522. In some embodiments, the conductive element 542 may include a solder material(s), which may include alloys of gold and tin solder or alloys of silver and tin solder, or other suitable materials. In some embodiments, the recess or concave of the vias 522 may configured to define the locations of the conductive elements 542, which thereby prevents the bridge or short between the conductive elements 542.

Please refer back to FIG. 1, each of the interconnection structures 51 may be disposed on the surface 10s2 of the circuit structure 10. In some embodiments, the interconnection structure 51 may be electrically connected to the circuit structure 10. In some embodiments, the interconnection structure 51 may be disposed at the surface 31s3 of the power regulating component 31. In some embodiments, the interconnection structure 51 may penetrate the encapsulant 21. In some embodiments, the interconnection structure 51 may penetrate the encapsulant 22. In some embodiments, the interconnection structure 51 may be electrically connected to the redistribution layer 52. In some embodiments, the interconnection structure 51 may include a conductive pillar or a conductive via which is tapered toward the circuit structure 10. In some embodiments, the thickness of the interconnection structures 51 (or a length between the upper surface and lower surface of the interconnection structures 51) may be greater than that of the power regulating component 31. In some embodiments, the thickness of the interconnection structures 51 may be less than that of the electronic component 40.

Each of the terminals 55 may be disposed on or over the surface 40s2 of the electronic component 40. In some embodiments, each of the terminals 55 may include multiple stacked conductive elements. The terminals 55 may be electrically connected to the circuit structure 60. In some embodiments, each of the terminals 55 may include a pad 551 and a via 552. The pad 551 may be disposed on or over the surface 40s2 of the electronic component 40. The pad 551 may be embedded within the encapsulant 24. The pad 551 may include copper, aluminum, gold, silver, tungsten, nickel, a combination thereof or other suitable materials. The via 552 may be disposed on or over the pad 551. The via 552 may be embedded within the encapsulant 24. The via 552 may be tapered toward the pad 551. In some embodiments, the via 552 may include a seed layer and a conductive material on the seed layer.

In some embodiments, each of the interconnection structures 56 may be disposed on or over the redistribution layer 52. In some embodiments, the interconnection structure 56 may be disposed at the surface 40s3 of the electronic component 40. In some embodiments, the interconnection structure 56 may penetrate the encapsulant 24. In some embodiments, the interconnection structure 56 may partially penetrate the encapsulant 23. In some embodiments, the interconnection structure 56 may include a conductive pillar or a conductive via which is tapered toward the circuit structure 10. In some embodiments, the interconnection structure 56 may be electrically connected to the redistribution layer 52. In some embodiments, the interconnection structure 56 may have a dimension (e.g., diameter or width) greater than that of the interconnection structure 51. In some embodiments, the thickness of the interconnection structure 56 (or a length between the upper surface and lower surface of the interconnection structures 56) may be greater than that of the interconnection structure 51.

In some embodiments, the circuit structure 60 may be disposed on or over the encapsulant 24. In some embodiments, the circuit structure 60 may be electrically connected to the interconnection structure 56. In some embodiments, the circuit structure 60 may be electrically connected to the electronic component 40 through the terminals 55. The circuit structure 60 may include a substrate 61, a conductive layer 62, a conductive layer 63, an interconnection 64, and a dielectric layer 65. The circuit structure 60 may have a surface 60s1 (or a lower surface) and a surface 60s2 (or an upper surface) opposite to the surface 60s1.

The substrate 61 may be a core substrate. The core substrate may include prepreg, ABF or other suitable materials. In some embodiments, a resin material used in the core substrate may be a fiber-reinforced resin so as to strengthen the core substrate, and the reinforcing fibers may be, without limitation to, glass fibers or Kevlar fibers (aramid fibers). The lower surface of the substrate 61 may be defined as the surface 60s1. The upper surface of the substrate 61 may be defined as the surface 60s2.

The conductive layer 62 may be disposed under, within, and/or adjacent to the surface 60s1 of the circuit structure 60. The conductive layer 63 may be disposed over, within, and/or adjacent to the surface 60s2 of the circuit structure 60. The conductive layer 63 may be electrically connected to an external device (not shown), such as a printed circuit board or other suitable components. The interconnection 64 may be disposed within the substrate 61. The interconnection 64 may electrically connect the conductive layer 62 to the conductive layer 63. The interconnection 64 may include a conductive via, which is tapered toward the surface 60s1 of the circuit structure 60. Each of the conductive layer 62, conductive layer 63, and interconnection 64 may include a seed layer (not shown) and a conductive material on the seed layer. The seed layer may include metal, metal oxide, metal nitride, metal carbide, metal alloy, or suitable materials. For example, the seed layer may include tantalum nitride, tantalum, titanium nitride, titanium, cobalt tungsten, tungsten nitride, or the like. The conductive material may include copper, aluminum, tungsten, chromium, gold, silver, other suitable materials, or a combination thereof.

The dielectric layer 65 may be disposed over the surface 60s2 of the circuit structure 60. The dielectric layer 65 may be patterned to expose a portion of the conductive layer 63. The dielectric layer 65 may include a solder resist, such as a polymer material including bismaleimide triazine, polypropylene or an epoxy-based material.

In some embodiments, power P1 may be transmitted from the circuit structure 10 to the electronic component 40 through the interconnection structure 51, redistribution layer 52, terminals 53, power regulating component 31, and terminals 54. In some embodiments, power P1 may be transmitted to the electronic component 40 through the surface 40s1.

In some embodiments, power P2 may be transmitted from the circuit structure 10 to the electronic component 40 through the interconnection structure 51, redistribution layer 52, terminals 53, power regulating component 32, and terminals 54. In some embodiments, power P2 may be transmitted to the electronic component 40 through the surface 40s1. In some embodiments, power P1 (e.g., voltage) may be different from the power P2. In some embodiments, power P1 may be the same as the power P2. In some embodiments, the power P1 may be referred to as the first power, and the power P2 may be referred to as the second power.

In some embodiments, signal S1 may be transmitted from the surface 40s2 of the electronic component 40 to the circuit structure 60. In some embodiments, signal S1 may be transmitted from the electronic component 40 to the circuit structure 10 through the circuit structure 60, the interconnection structure 56, the redistribution layer 52, and the interconnection structure 51.

Each of the arrows of power P1, power P2, and signal S1 may indicate a transmission path. In this disclosure, the transmission path may indicate a structure(s) that power (or a signal) passes through.

In a comparative example, an interconnection structure, configured to transmit power, is disposed between a PMIC and a circuit structure. The interconnection structure is disposed at the side of an electronic component. Consequently, power flows through the interconnection structure and travels through the side of the electronic component, resulting in a relatively long transmission path. In this disclosure, power flows through the side of the PMIC (e.g., the power regulating component 31 or power regulating component 32) rather than the side of the electronic component (e.g., the electronic component 40). Consequently, the transmission path for power is relatively short, leading to decreased power loss.

In a comparative example, the terminals of a PMIC or electronic component are connected to pads exposed by a solder resist, and the terminal density is limited by the solder resist opening (SRO) process. In this embodiment, the terminals of the power regulating component 31, power regulating component 32, and electronic components 40 are each connected to the redistribution layer 52, which may be patterned with a higher density. For example, the terminal pitch of a PMIC is approximately 170 μm, whereas the terminal pitch (e.g., the pitch of the terminals 53) of a PMIC (e.g., the power regulating component 31) is approximately 80 μm. Thus, the terminal density of the electronic device 1a can be enhanced.

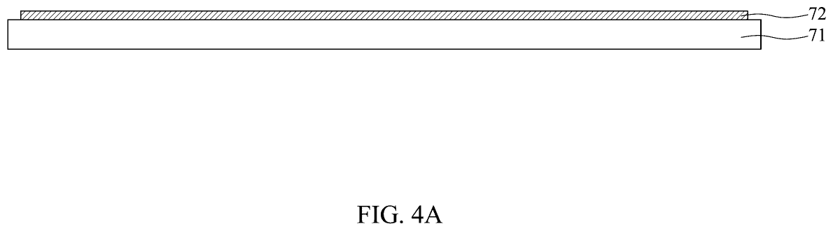

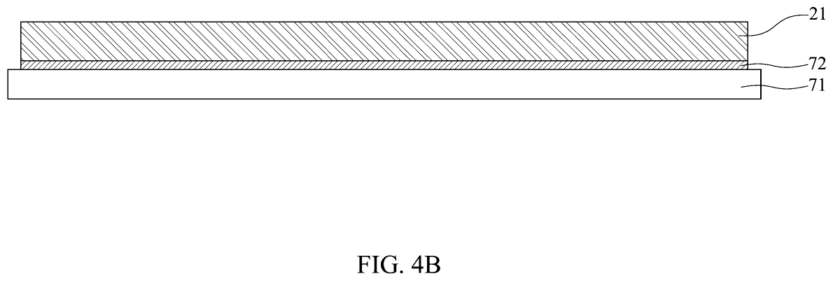

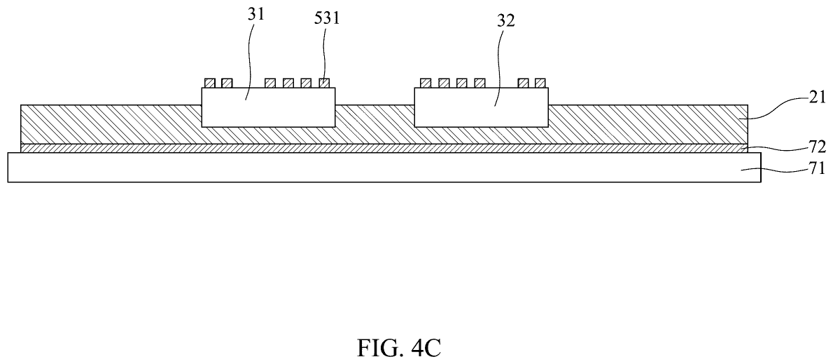

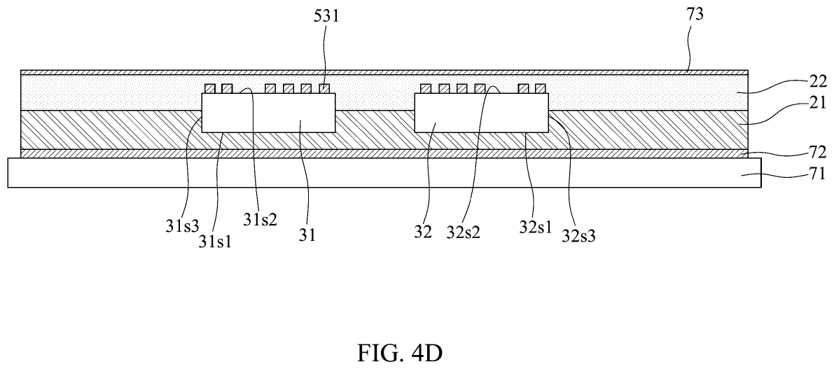

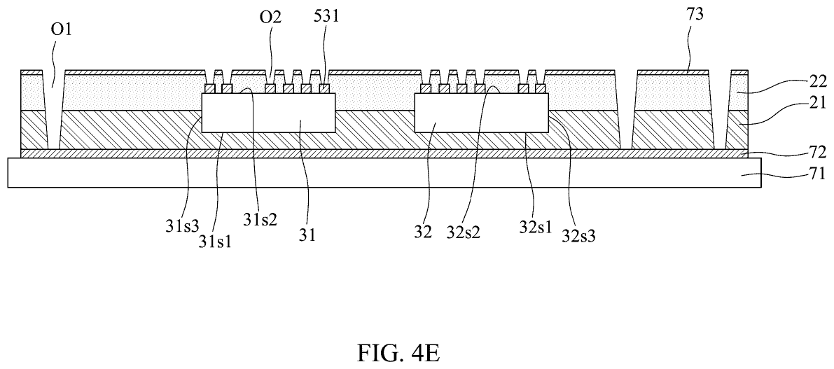

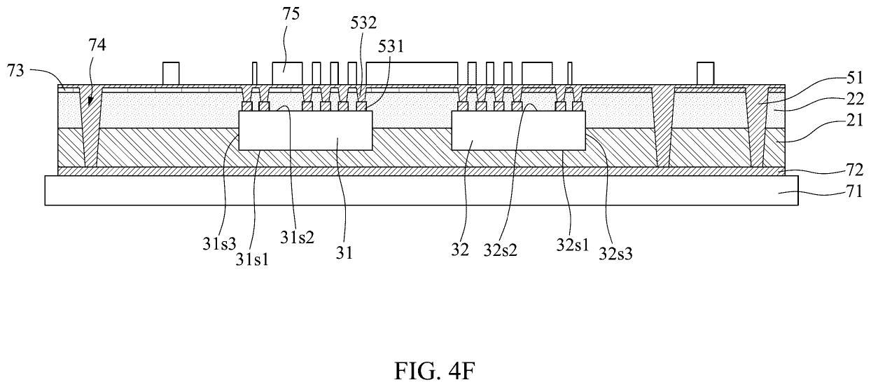

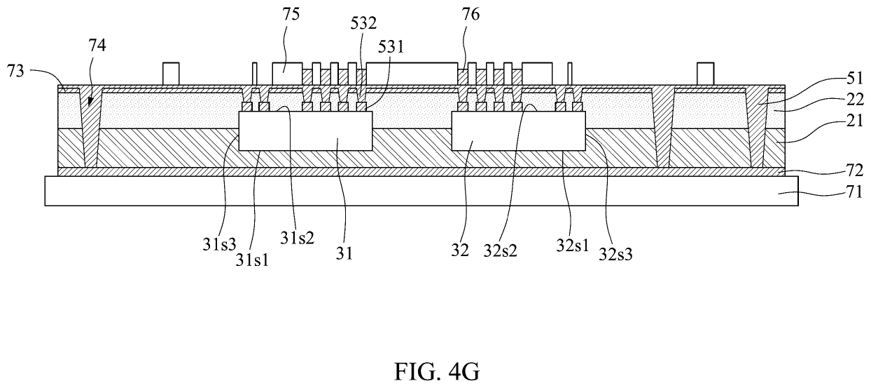

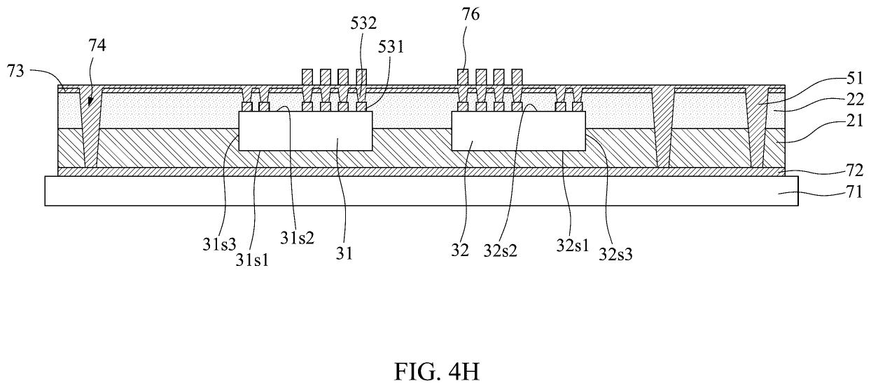

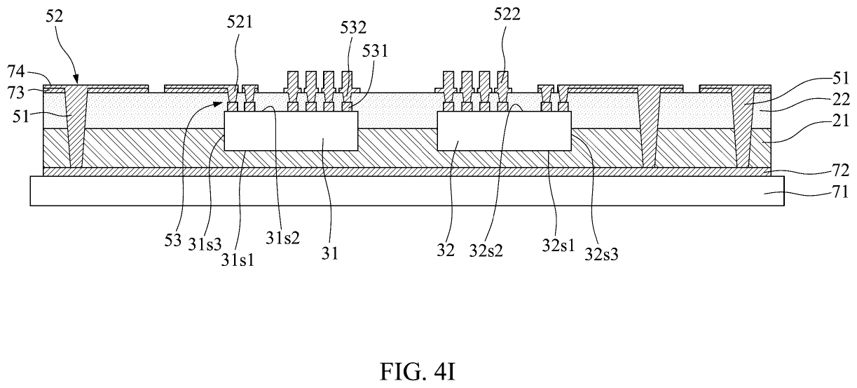

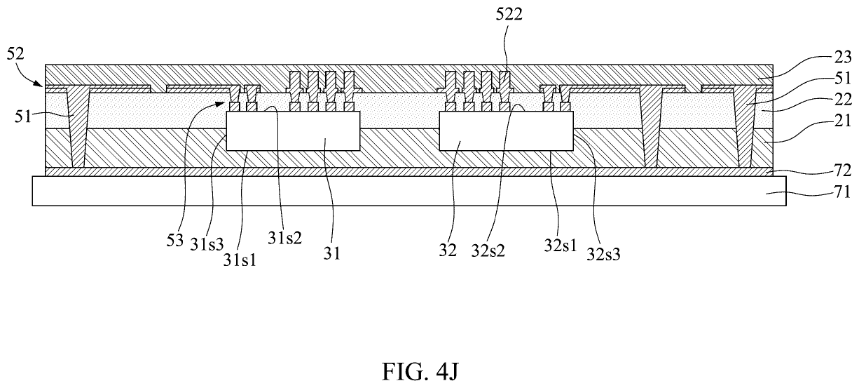

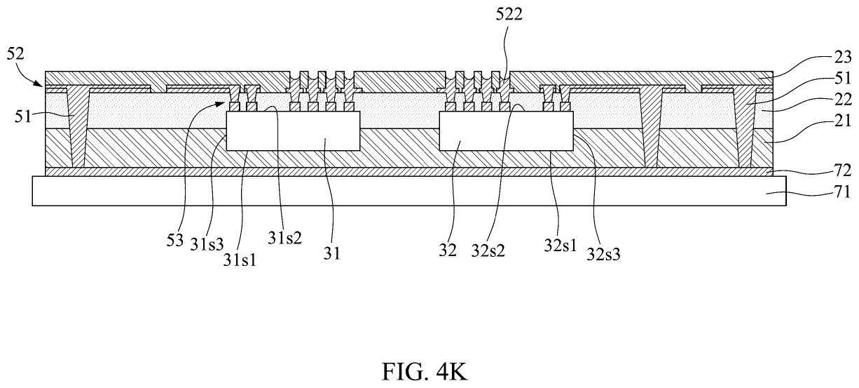

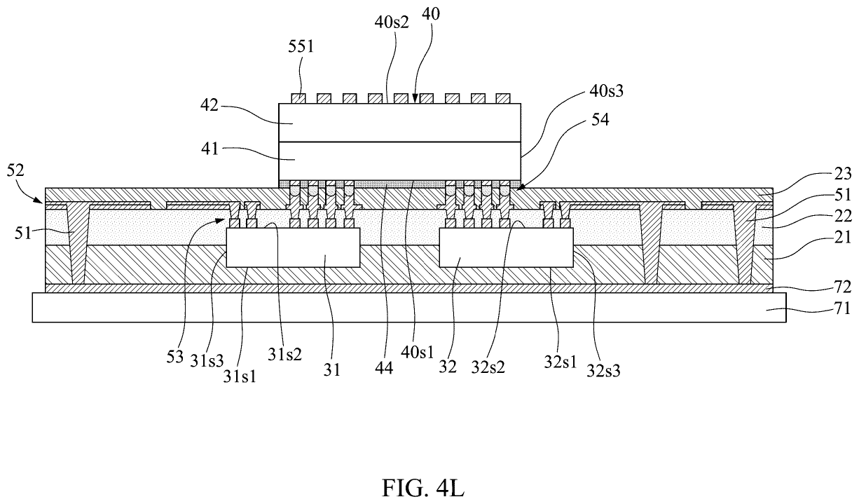

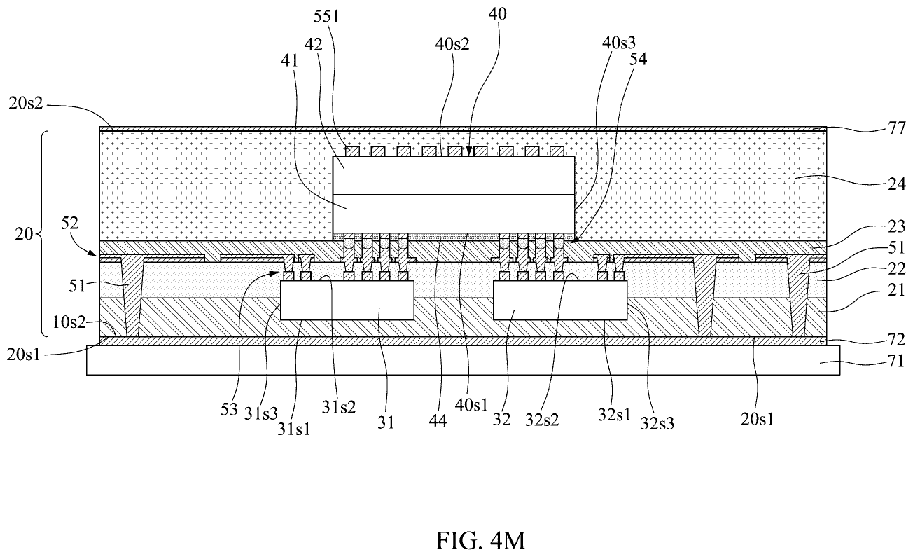

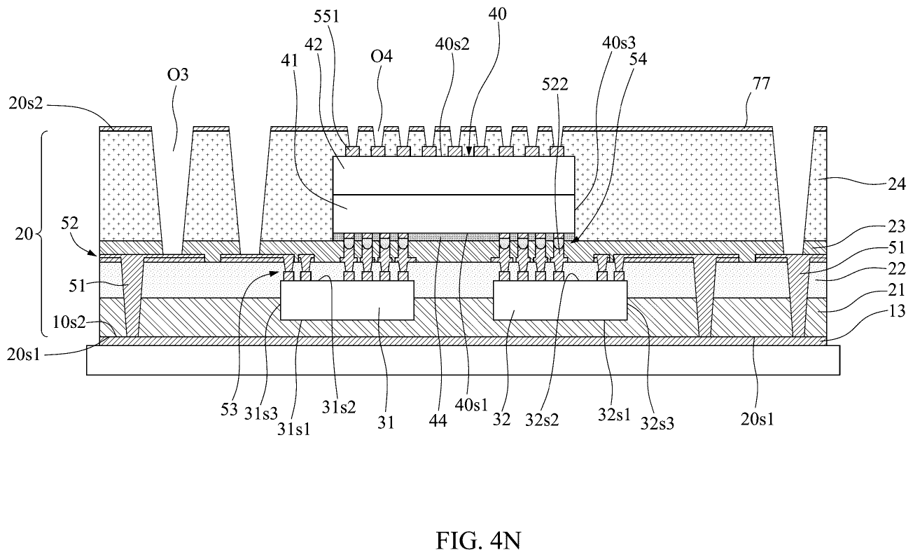

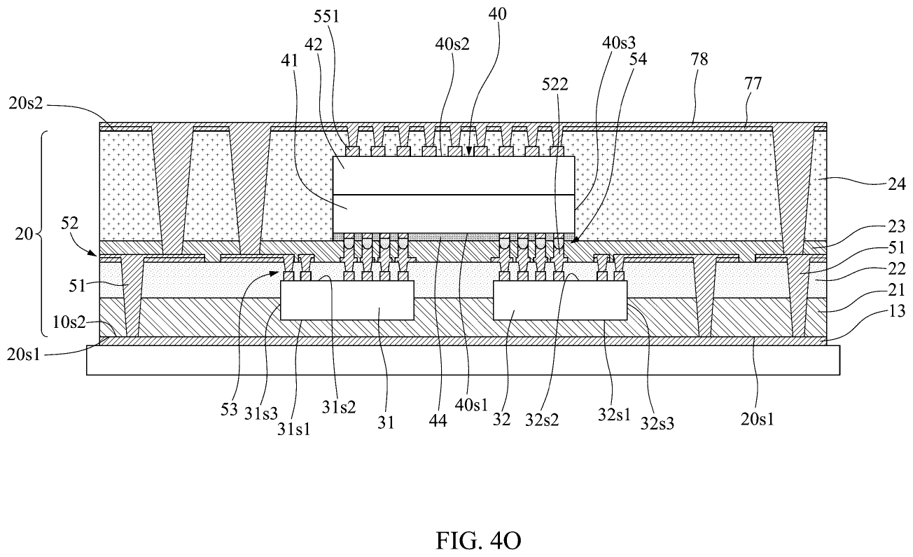

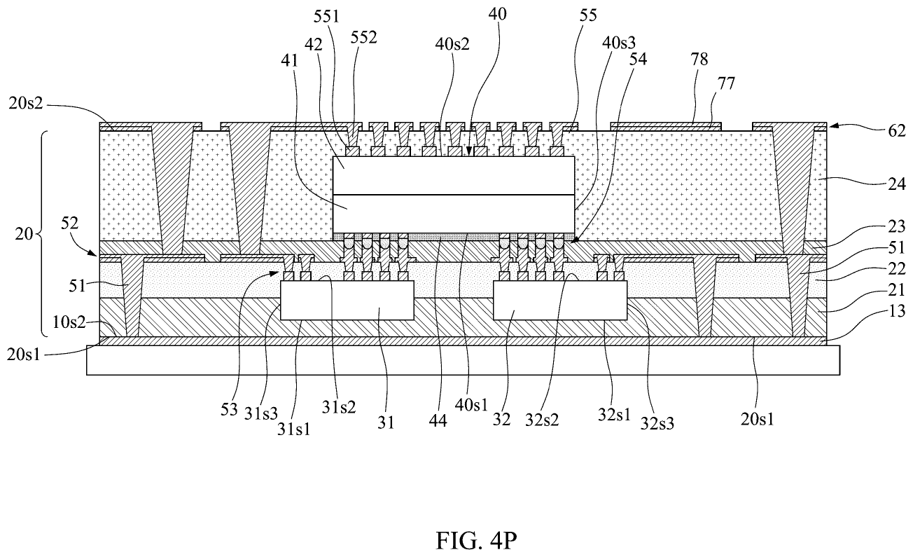

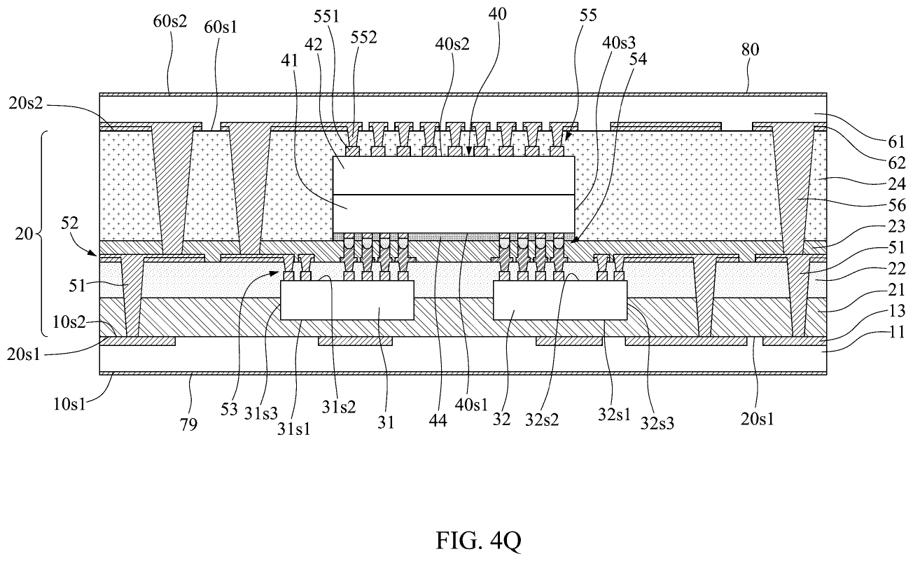

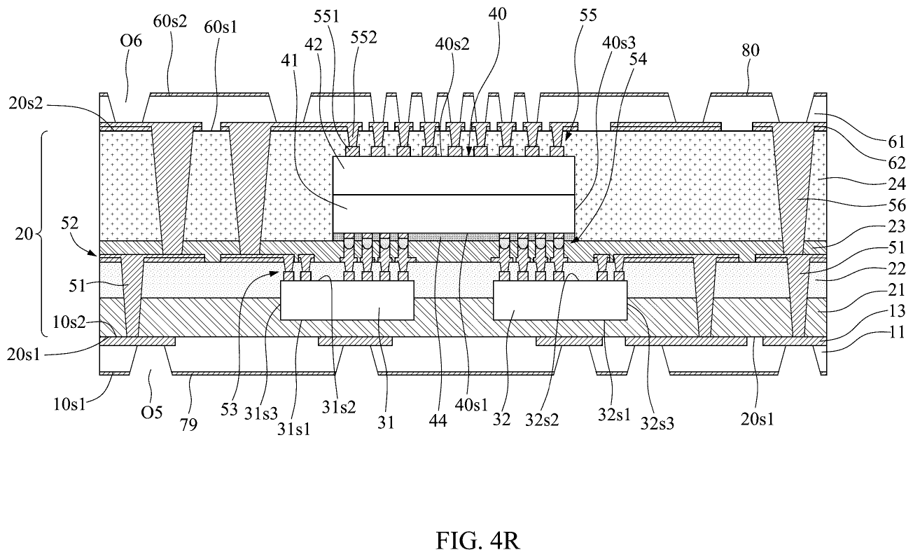

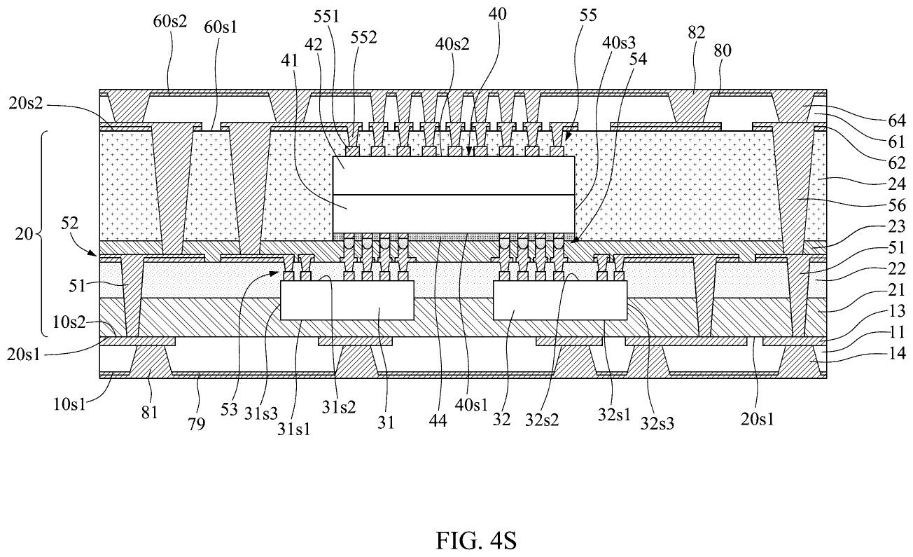

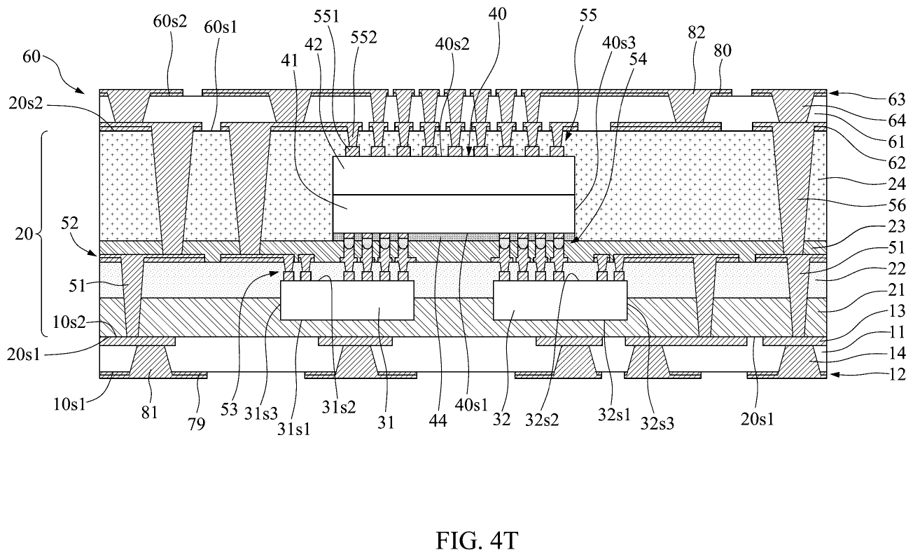

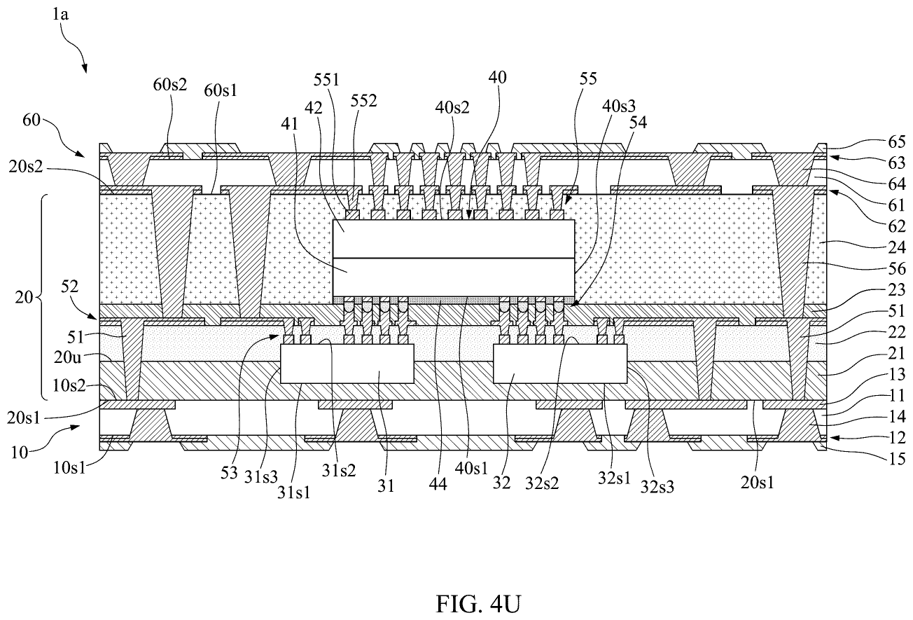

FIG. 4A to FIG. 4U illustrate various stages of an example of a method for manufacturing an electronic device according to some embodiments of the present disclosure.

Referring to FIG. 4A, a supporter 71 may be provided. The supporter 71 may include a glass supporter, a silicon supporter, a plastic supporter, a ceramic supporter, or other suitable supporters. The supporter 71 will be removed in subsequent stages. A conductive material 72 may be formed on or over the supporter 71. The conductive material 72 may be attached to the supporter through an adhesive layer or a release film (not shown).

Referring to FIG. 4B, the encapsulant 21 may be formed on or over the conductive material 72.

Referring to FIG. 4C, the power regulating component 31 and the power regulating component 32 may be attached to the encapsulant 21. In some embodiments, the power regulating component 31 and power regulating component 32 may be inserted and penetrate a portion of the encapsulant 21. In some embodiments, each of lateral surface (or side) of the power regulating component 31 (or power regulating component 32) may be inserted into the encapsulant 21 at different depths. In some embodiments, the power regulating component 31 (or power regulating component 32) may be inserted into the encapsulant 21 obliquely. For example, the lateral surface(s) of the power regulating component 31 (or power regulating component 32) may be slanted with respect to the upper surface of the encapsulant 21.

Referring to FIG. 4D, the encapsulant 22 may be formed on the encapsulant 21. The encapsulant 22 may cover the pads 531. A conductive material 73 may be formed on or over the encapsulant 22.

Referring to FIG. 4E, the conductive material 73 may be patterned. The encapsulant 22 may be patterned. The encapsulant 21 may be patterned. As a result, openings O1 may be formed to expose the conductive material 72. Openings O2 may be formed to expose the pads 531. In some conditions, the power regulating component 31 (or power regulating component 32) may be inserted into the encapsulant 21 obliquely which causes the pads 531 to be shifted from desired locations. In this embodiment, the openings O2 may be formed by a laser ablation, sand blasting, or other suitable techniques. Such openings O2 may be defined or formed based on shifted locations of the pads 531. As a result, the issues resulting from pad shifts, such as disconnection between pads 531 and other conductive elements, can be prevented.

Referring to FIG. 4F, A conductive material 74 may be formed within the openings O1 to form the interconnection structure 51 and within the openings O2 to form the via 532. The conductive material 74 may be formed on or over the conductive material 73. The photosensitive material 75 may be formed on the conductive materials 73 and 74. In some embodiments, a grinding technique or an etch back process may be performed on the conductive material 73 and/or conductive material 74.

Referring to FIG. 4G, a conductive material 76 may be formed within the openings of the photosensitive material 75.

Referring to FIG. 4H, the photosensitive material 75 may be removed to expose the conductive material 74 (or conductive material 73).

Referring to FIG. 4I, an etching technique may be performed. The conductive material 73 which is exposed may be removed. The conductive material 74 which is exposed may be removed. As a result, the redistribution layer 52, including the conductive layer 521 and vias 522, may be defined. A portion of the encapsulant 22 may be exposed. In some embodiments, one or more etching techniques and/or lithography techniques may be performed to define the patterns of the redistribution layer 52, including the conductive layer 521 and vias 522.

Referring to FIG. 4J, the encapsulant 23 may be formed to cover the redistribution layer 52 and the encapsulant 22.

Referring to FIG. 4K, a grinding and/or an etching technique may be performed to remove a portion of the encapsulant 23. A portion of the via 522 may be removed to define a curved surface which exposed by the encapsulant 23.

Referring to FIG. 4L, the electronic component 40 may be bonded to the power regulating component 31 and power regulating component 32 through the terminals 53 and terminals 54.

Referring to FIG. 4M, the encapsulant 24 may be formed on the encapsulant 23. The encapsulant 24 may encapsulate the electronic component 40. A conductive material 77 may be formed on the encapsulant 24.

Referring to FIG. 4N, the conductive material 77 may be patterned. The encapsulant 24 may be patterned. As a result, Openings O3 may be formed to expose the redistribution layer 52. Openings O4 may be formed to expose the pads 551. In some conditions, when the electronic component 40 is connected to the vias 522 which are tilted, the pads 551 may be tilted. In this embodiment, the openings O4 may be formed by a laser ablation, sand blasting, or other suitable techniques. Such openings O4 may be defined or formed based on shifted locations of the pads 551. As a result, the issues resulting from pad shifts, such as disconnection between pads 551 and other conductive elements, can be prevented.

Referring to FIG. 4O, a conductive material 78 may be formed on the conductive material 77. The conductive material 78 may be formed within the openings O3 to define the interconnection structures 56 and within the openings O4 to define the vias 552. In some embodiments, a grinding technique or an etch back process may be performed on the conductive material 77 and/or conductive material 78.

Referring to FIG. 4P, the supporter 71 may be removed. The conductive material 72 may be patterned to define the conductive layer 13. The conductive material 77 and/or conductive material 78 may be patterned to define the conductive layer 62.

Referring to FIG. 4Q, the substrate 11 may be formed under the encapsulant 21. A conductive material 79 may be formed under the substrate 11. The substrate 61 may be formed on the encapsulant 24. A conductive material 80 may be formed over the substrate 61.

Referring to FIG. 4R, the substrate 11 and the conductive material 79 may be patterned to form openings O5, and the conductive layer 13 may be exposed. The substrate 61 and the conductive material 80 may be patterned to form openings O6, and the conductive layer 62 may be exposed.

Referring to FIG. 4S, a conductive material 81 may be formed under the substrate 11 and within the openings O5 to define the interconnection 14. A conductive material 82 may be formed over the substrate 61 and within the openings O6 to define the interconnection 64.

Referring to FIG. 4T, the conductive materials 79 and/or 81 may be patterned to define the conductive layer 12. The conductive materials 80 and/or 82 may be patterned to define the conductive layer 63.

Referring to FIG. 4U, the dielectric layer 15 may be formed under the substrate 11 and expose a portion of the conductive layer 12. The dielectric layer 65 may be formed over the substrate 61 and expose a portion of the conductive layer 63. As a result, an electronic device (e.g., the electronic device 1a) may be produced.

In some embodiments, an electronic device includes an electronic component, a first encapsulant, a second encapsulant, and a first power regulating component. The encapsulant has an active surface and a backside surface configured to receive a first power. The first encapsulant at least partially encapsulates the electronic component. The second encapsulant is disposed under the first encapsulant. The first power regulating component is configured to transmit the first power to the electronic component and at least partially embedded within the second encapsulant. In some embodiments, the electronic component overhangs the first power regulating component. In some embodiments, a second power regulating component is configured to transmit a second power to the electronic component and disposed under the electronic component. In some embodiments, the first power is different from the second power. In some embodiments, the electronic component overhangs the second power regulating component. In some embodiments, a second encapsulant partially encapsulating the first power regulating component, and a first conductive via penetrating the second encapsulant and electrically connected to the electronic component. In some embodiments, a third encapsulant disposed between the first encapsulant and the second encapsulant, and a second conductive via penetrating the third encapsulant and electrically connected to the first power regulating component through the first conductive via. In some embodiments, a third encapsulant partially encapsulating the first power regulating component, a third conductive via penetrating the second encapsulant and the third encapsulant, and the third conductive via is electrically connected to the first power regulating component. In some embodiments, a fourth conductive via penetrating the first encapsulant and electrically connected to the electronic component. In some embodiments, the first encapsulant covers the active surface of the electronic component.

In some embodiments, an electronic device includes an electronic component, a power regulating component, and a first interconnection structure. The electronic component has an active surface and a backside surface configured to receive a power. The power regulating component is configured to transmit the power to the electronic component. The first interconnection structure is disposed at a side of the power regulating component configured to transmit the power. In some embodiments, the first interconnection structure is free from laterally overlapping the electronic component. In some embodiments, the power regulating component is free from laterally overlapping the electronic component. In some embodiments, a first circuit structure configured to support the first interconnection structure, and the power regulating component is spaced apart from the first circuit structure. In some embodiments, the power regulating component is closer to the first circuit structure than the electronic component is. In some embodiments, a second circuit structure over the active surface of the electronic component, and a second interconnection structure connected to the second circuit structure and disposed at a side of the electronic component. In some embodiments, a first encapsulant and a second encapsulant disposed over the first encapsulant, wherein the first encapsulant and the second encapsulant collectively encapsulates the power regulating component. In some embodiments, wherein the first interconnection structure penetrates the first encapsulant and the second encapsulant. In some embodiments, a redistribution layer disposed over the second encapsulant, wherein the redistribution layer electrically connects the power regulating component to the first interconnection structure. In some embodiments, a third encapsulant disposed over the second encapsulant and encapsulating the redistribution layer. In some embodiments, the electronic component is free from laterally overlapping the third encapsulant. In some embodiments, a fourth encapsulant disposed over the third encapsulant and encapsulating the electronic component. In some embodiments, a second interconnection structure penetrating the third encapsulant and the fourth encapsulant. In some embodiments, the third encapsulant covers an upper surface of the redistribution layer. In some embodiments, a thickness of the power regulating component is less than a thickness of the first interconnection structure. In some embodiments, a thickness of the electronic component is greater than the thickness of the first interconnection structure.

In some embodiments, an electronic device includes a first interposer, a power regulating component, and an electronic component. The power regulating component is embedded within the first interposer and includes a terminal exposed by the first interposer. The electronic component is bonded to the terminal of the power regulating component. The electronic component has an active surface and a backside surface configured to receive a power from the power regulating component. In some embodiments, an interconnection structure configured to transmit the power and embedded within the interposer. In some embodiments, a thickness of the interconnection structure is greater than a thickness of the power regulating component. In some embodiments, a redistribution layer disposed over the interposer, wherein the electronic component is bonded to the terminal of the power regulating component through the redistribution layer.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Two surfaces can be deemed to be coplanar or substantially coplanar if a displacement between the two surfaces is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
an electronic component having an active surface and a backside surface; and
a first power regulating component disposed under the electronic component and facing the backside surface, wherein the first power regulating component is configured to transmit a first power to the electronic component through the backside surface.

2. The electronic device of claim 1, wherein the electronic component overhangs the first power regulating component.

3. The electronic device of claim 2, further comprising:
a second power regulating component configured to transmit a second power to the electronic component and disposed under the electronic component.

4. The electronic device of claim 3, wherein the first power is different from the second power.

5. The electronic device of claim 1, further comprising:
a first encapsulant partially encapsulating the first power regulating component; and
a first conductive via penetrating the first encapsulant and electrically connected to the electronic component.

6. The electronic device of claim 5, further comprising:
a second encapsulant disposed over the first encapsulant; and
a second conductive via penetrating the second encapsulant and electrically connected to the first power regulating component through the first conductive via.

7. The electronic device of claim 6, wherein the second conductive via and the second encapsulant define a spaced accommodating a conductive element electrically connected to the electronic component.

8. An electronic device, comprising:
a power regulating component configured to receive a first power flowing through a lateral surface of the power regulating component; and
an electronic component disposed over the power regulating component and having an active surface and a backside surface, wherein the electronic component is configured to receive a second power from the power regulating component through the backside surface.

9. The electronic device of claim 8, further comprising a first interconnection structure free from laterally overlapping the electronic component.

10. The electronic device of claim 9, further comprising:
a first circuit structure configured to support the first interconnection structure, wherein the power regulating component is spaced apart from the first circuit structure.

11. The electronic device of claim 10, further comprising:
a first encapsulant connecting the first circuit structure to the power regulating component;
a second encapsulant covering the power regulating component,
wherein the first interconnection structure penetrates the first encapsulant and the second encapsulant.

12. The electronic device of claim 10, further comprising:
a second circuit structure over the active surface of the electronic component; and
a second interconnection structure connected to the second circuit structure and disposed at a side of the electronic component.

13. The electronic device of claim 8, further comprising:
a first encapsulant and a second encapsulant in contact with the first encapsulant, and an interface between the first encapsulant and the second encapsulant intersects a sidewall of the power regulating component.

14. The electronic device of claim 13, further comprising:
a first interconnection structure penetrating the first encapsulant and the second encapsulant; and
a redistribution layer disposed over the second encapsulant, wherein the redistribution layer electrically connects the power regulating component to the first interconnection structure.

15. The electronic device of claim 14, further comprising:
a third encapsulant disposed over the second encapsulant and encapsulating the redistribution layer.

16. The electronic device of claim 15, further comprising:
a fourth encapsulant disposed over the third encapsulant and encapsulating the electronic component.

17. The electronic device of claim 16, further comprising:
a second interconnection structure penetrating the third encapsulant and the fourth encapsulant.

18. The electronic device of claim 17, wherein the electronic component is configured to transmit a signal from the active surface to the first interconnection structure through the second interconnection structure and the redistribution layer.

19. An electronic device, comprising:
an interposer;
a power regulating component embedded within the interposer and comprising a terminal exposed by the interposer; and
an electronic component connected to the terminal of the power regulating component, wherein the electronic component has a backside surface configured to receive a power from the power regulating component.

20. The electronic device of claim 19, wherein the interposer is configured to provide the power regulating component with the power and further configured to transmit a signal from the electronic component.
